(19) United States
(12) Patent Application Publication
(10) Pub. No.: US 2020/0149162 A1
(43) Pub. Date: May 14, 2020

(54) FLUID CONTROL DEVICE

(71) Applicant: FUJIKIN INCORPORATED, Osaka (JP)

(72) Inventors: Atsushi HIDAKA, Osaka-shi (JP); Takatoshi NAKATANI, Osaka-shi (JP); Keisuke NAKATSUJI, Osaka-shi (JP); Keiji HIRAO, Osaka-shi (JP); Yukio MINAMI, Osaka-shi (JP); Nobukazu IKEDA, Osaka-shi (JP)

(73) Assignee: FUJIKIN INCORPORATED, Osaka (JP)

(21) Appl. No.: 16/628,193

(22) PCT Filed: Jul. 20, 2018
(86) PCT No.: PCT/JP2018/027233

§ 371 Date: Jan. 2, 2020

(30) Foreign Application Priority Data
Jul. 25, 2017 (JP) 2017-144028

(51) Int. Cl. C23C 16/448; H05B 3/06; H05B 3/12

(52) U.S. Cl. CPC C23C 16/4485; H05B 3/12; H05B 3/06

(57) ABSTRACT

In order to optimally supply a raw material by using a heater, the fluid control device (100) includes a fluid heating section (1) provided with a flow path or a fluid accommodation portion inside, and a heater (10) for heating the fluid heating section, the heater having a heating element (10a) and a metallic heat transfer member (10b) thermally connected to the heating element and arranged so as to surround the fluid heating section, and the surface of the heat transfer member facing the fluid heating section includes a surface (S1) subjected to surface treatment for improving heat dissipation.

### TECHNICAL FIELD

The present invention relates to a fluid control device used for a semiconductor manufacturing device or a chemical plant, and more particularly, to a fluid control device provided with a heater for heating a fluid.

### BACKGROUND OF INVENTION

Conventionally, in a semiconductor manufacturing device for a film deposition by metal organic chemical vapor deposition (MOCVD), for example, a raw material vaporization supply device for supplying a raw material gas to a process chamber has been used (for example, Patent Document 1).

In some raw material vaporization supply devices, an organometallic liquid raw material such as TEOS (Tetraethyl orthosilicate) is stored in a storage tank, pressurized inert gas is supplied to the storage tank, and the liquid raw material is extruded at a constant pressure and supplied to a vaporizer. The supplied liquid raw material is vaporized by a heater disposed around the vaporizer, and the vaporized gas is controlled to a predetermined flow rate by a flow rate control device, and supplied to the semiconductor manufacturing device.

Some organometallic materials as raw materials have boiling points exceeding 150° C., for example, the boiling point of the above-mentioned TEOS is about 169° C. For this reason, the raw material vaporization supply device is configured to be able to heat the liquid raw material to a relatively high temperature, for example, to a temperature of 200° C. or higher.

Further, in order to prevent condensation (re-devolatilization) of the vaporized raw material, the raw material vaporization supply device is required to supply gas to the process chamber through a flow path heated to a high temperature. Moreover, in order to efficiently vaporize the organometallic material, the liquid raw material may be heated in advance before being supplied to the vaporizer. Thus, in the raw material vaporization supply device, heaters are disposed at necessary positions for heating fluid heating sections (e.g., a vaporizer), each provided with a flow path or a fluid accommodating portion to a high temperature.

Patent Document 2 discloses a vaporization supply device including a preheating section for preheating a raw material liquid, a vaporizer for vaporizing the raw material liquid heated by the preheating section, and a high-temperature compatible pressure type flow rate control device for controlling a flow rate of the vaporized gas. In the vaporization supply device described in Patent Document 2, jacket heaters are used as means for heating the main body of the vaporizer, the flow path, and the like. The jacket heaters are attached in close contact from the outside so as to cover the vaporizer, piping, and the like, and the fluid can be heated from the outside by heating wires (nichrome wire or the like) carrying current in the jacket heaters.

### PRIOR-ART DOCUMENTS

### Patent Documents

Patent Document 1: Japanese Laid-Open Patent Application No. JP2014-114463

Patent Document 2: international Patent Publication No. WO 2016/174832

### SUMMARY OF INVENTION

### Problems to be Solved by Invention

A jacket heater has an advantage of high convenience because it is relatively easy to attach and detach. However, on the other hand, in the case of using a jacket heater, there is a problem in that, for example, a gap is formed between the jacket heater and the fluid heating section, thermal conductivities tend to vary depending on places, and it is difficult to uniformly heat an internal fluid. In addition, in the jacket heater, since it is necessary to arrange heating wires uniformly over a wide range in order to improve the heat uniformity, there is a problem that labor and cost for manufacturing are required.

The present invention has been made in view of the above-mentioned problems, and a main object is to provide a fluid control device capable of efficiently and uniformly heating and supplying a raw material using a heater.

### Means for Solving Problems

A fluid control device according to an embodiment of the present invention includes a fluid heating section provided with a flow path or a fluid accommodation portion inside, and a heater for heating the fluid heating section, wherein the heater has a heating element and a heat transfer member thermally connected to the heating element and arranged so as to surround the fluid heating section, and a surface of the heat transfer member facing the fluid heating section includes a surface treated for improving heat dissipation.

In an embodiment, the heat transfer member is formed from aluminum or an aluminum alloy, and the surface treated for improving the heat dissipation is an anodized surface.

In an embodiment, the heat transfer member has an inner surface facing the fluid heating section, and an outer surface located opposite side of the inner surface, the outer surface including a polished surface.

In an embodiment, the heat transfer member has an inner surface facing the fluid heating section, and an outer surface located opposite side of the inner surface, the outer surface including a mirror-finished surface.

In an embodiment, the heat transfer member is formed from aluminum or an aluminum alloy, the outer surface of the heat transfer member is a mirror-finished surface, and all surfaces of the heat transfer member other than the outer surface are anodized surfaces.

In an embodiment, the fluid control device comprises a vaporizing section, a preheating section for preheating liquid supplied to the vaporizing section, and a fluid control measurement section for controlling or measuring gas delivered from the vaporizing section, wherein the fluid heating section is at least one of the vaporizing section, the preheating section, and the fluid control measurement section.

In an embodiment, a gap is provided between a heat transfer member of a first heater for heating the pre-heating section and a heat transfer member of a second heater for heating the vaporizing section.

In an embodiment, the fluid control device further comprises an insulating member provided in the gap between the heat transfer member of the first heater and the heat transfer member of the second heater.

### Effect of Invention

According to the fluid control device related to the embodiments of the present invention, a heater having an improved energy utilization efficiency is used to heat the fluid uniformly and efficiently and supply the heated raw material appropriately while saving energy.

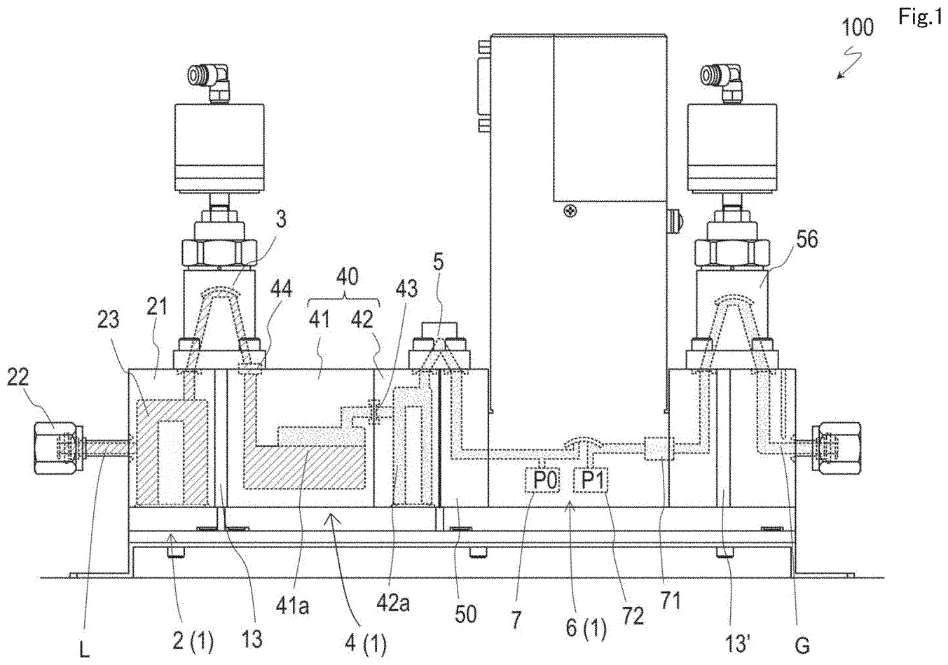

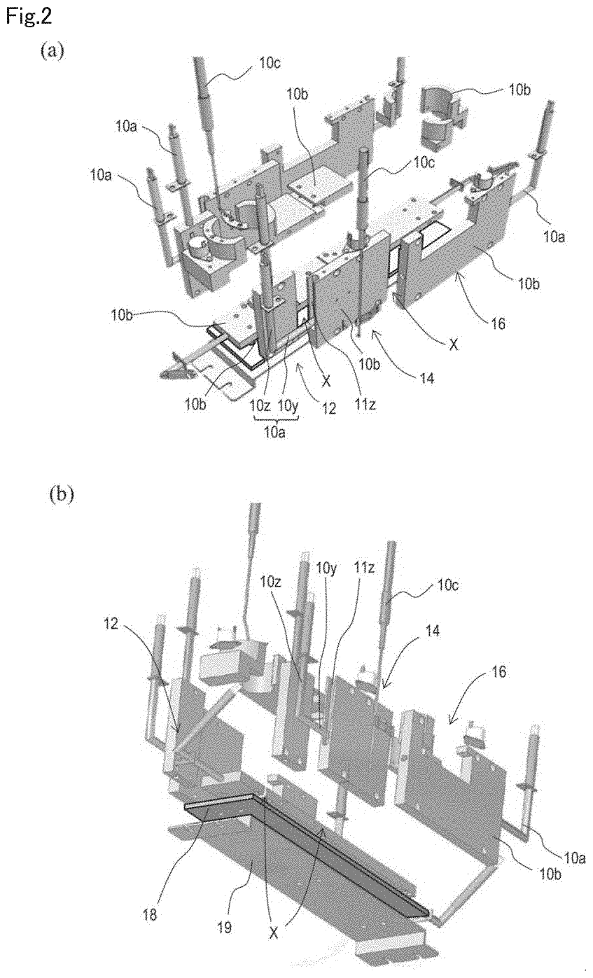

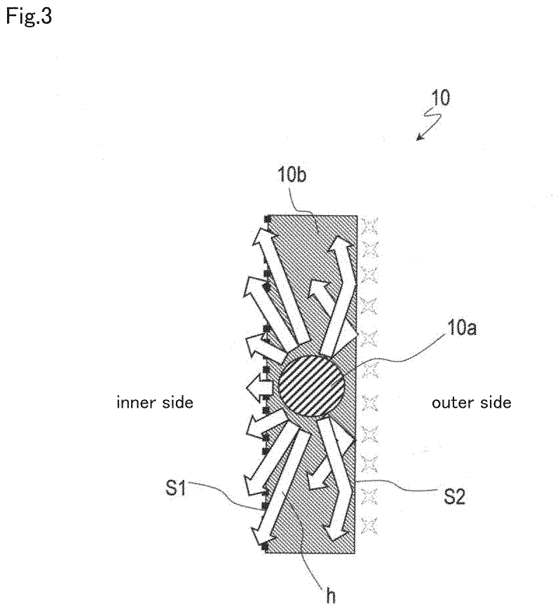

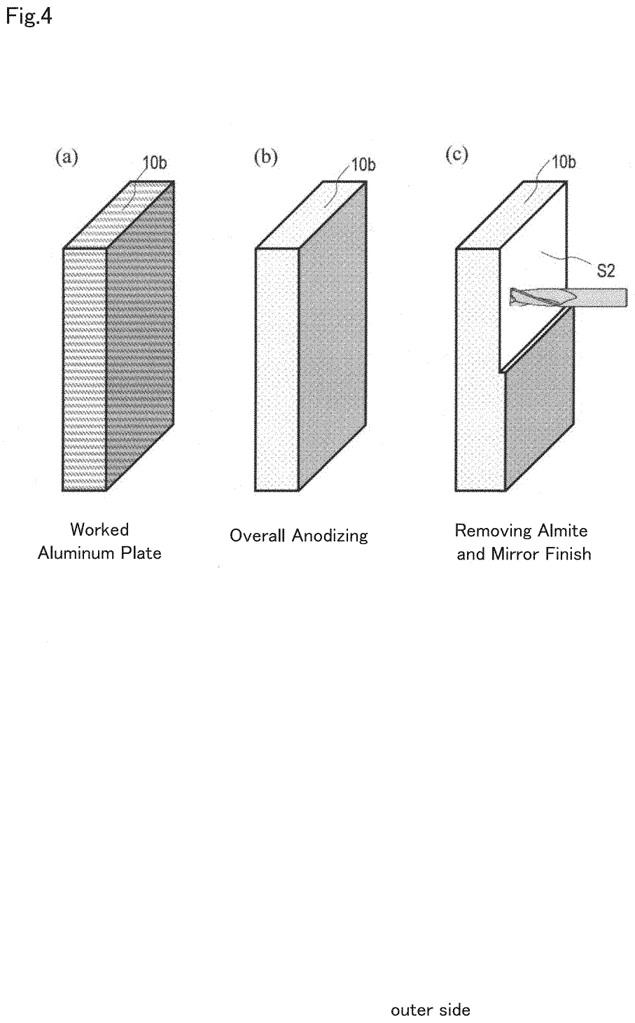

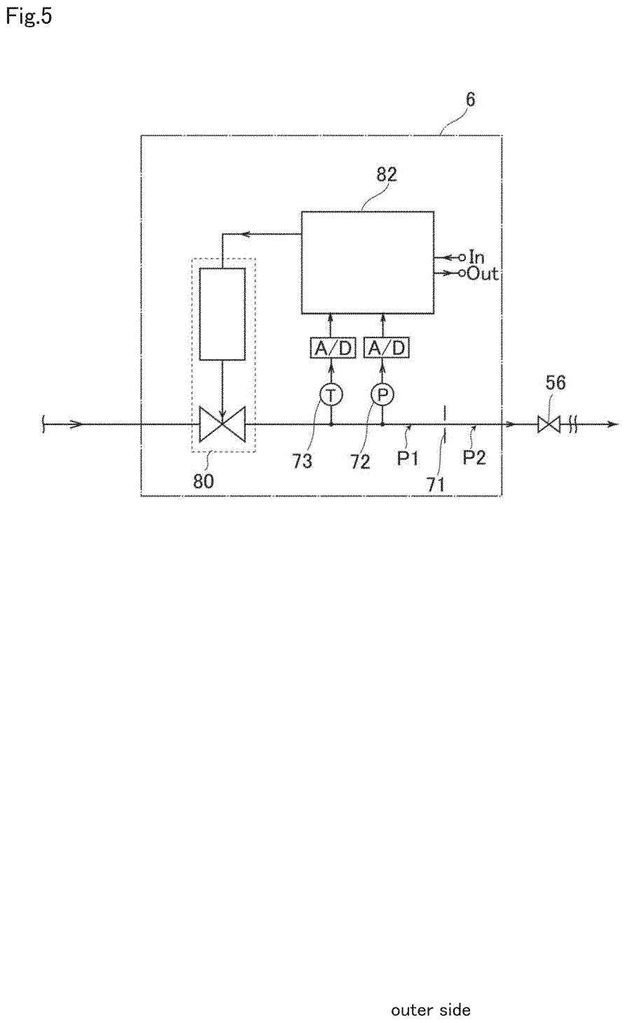

### BRIEF DESCRIPTION OF DRAWINGS

[FIG. 1] is a schematic illustration of a fluid control device according to an embodiment of the present invention.

[FIGS. 2] (a) and (b) are exploded perspective views of a heater, respectively, when viewed from an obliquely upper side and when viewed from an obliquely lower side.

[FIG. 3] is a cross-sectional view of a heat transfer member of a heater according to an embodiment of the present invention.

[FIGS. 4] (a) to (c) are diagrams showing the manufacturing process of the heat transfer member of the heater according to the embodiment of the present invention, and show different processes, respectively.

[FIG. 5] is a schematic diagram showing a configuration example of a fluid control section according to an embodiment of the present invention.

### DETAILED DESCRIPTION OF EMBODIMENTS

Embodiments of the present invention will be described below with reference to the drawings, but the present invention is not limited to the following embodiments.

FIG. 1 shows a fluid control device 100 according to an embodiment of the present invention. The fluid control device 100 includes a vaporizing section 4 for generating a raw material gas G used in a semiconductor manufacturing device or the like, a preheating section 2 for preheating a liquid raw material L supplied to the vaporizing section 4, and a fluid control measurement section 6 for controlling or measuring the gas G delivered from the vaporizing section 4. In FIG. 1, a portion filled with the liquid material L is indicated by hatching with diagonal lines, and a portion through which the gas G flows is indicated by hatching with dots.

Each of the preheating section 2, the vaporizing section 4, and the fluid control measuring section 6 is provided as a fluid heating section 1 in which an internal fluid (liquid raw material L or gas G) is heated, and a flow path or a fluid accommodating portion is provided in each of the preheating section 2, the vaporizing section 4, and the fluid control measuring section 6. Each of these components is heated from the outside by a heater 10 respectively, which will be described later.

In the fluid control device 100, the vaporizing section 4 is connected to the preheating section 2 via a liquid filling valve 3. The vaporizing section 4 and the fluid control measurement section 6 communicate with each other via a flow path block 5 provided with a flow path inside. A pressure detector 7 for detecting a pressure P0 of the vaporized gas G is provided in a flow path between the vaporizing section 4 and the fluid control measurement section 6.

In this configuration, based on the pressure value detected by the pressure detector 7, the liquid filling valve 3 can be controlled so as to supply a predetermined amount of the liquid raw material L to the vaporizing section 4. In addition, by providing a liquid detecting section (not shown) for detecting that a liquid raw material L exceeding a predetermined amount is supplied to the vaporizing section 4 and closing the liquid filling valve 3 when the liquid detecting section detects a liquid, it is possible to prevent oversupply of the liquid raw material L to the vaporizing section 4. As the liquid detection section, as described in Patent Document 2, a thermometer (platinum resistance temperature detector, thermocouple, thermistor, or the like), a liquid level meter, a load cell, or the like disposed in the vaporizing chamber can be used.

In the present embodiment, the fluid control measurement section 6 is a known high-temperature compatible pressure type flow rate control device, and as described later, a flow rate of a gas flowing through an orifice member 71 can be controlled by adjusting an upstream pressure P1 of the orifice member 71 using a control valve.

However, the fluid control measurement section 6 is not limited to a pressure type flow rate control device, and may be a flow rate control device of various modes. The fluid control measurement section 6 may be a fluid measurement section such as a flow rate sensor or a concentration sensor. Hereinafter, the fluid control measurement section 6, which is a pressure type flow rate control device, may be described as the fluid control section 6.

The fluid control device 100 according to the present embodiment includes a first heater 12 for heating the preheating section 2, a second heater 14 for heating the vaporizing section 4, and a third heater 16 for heating the fluid control section 6 as heaters 10 that heat the fluid heating section 1 (here, the preheating section 2, the vaporizing section 4, and the fluid control section 6).

FIGS. 2(a) and 2(b) are exploded perspective views of the heaters 10 (the first heater 12, the second heater 14, and the third heater 16) when viewed from different angles. As shown in FIGS. 2(a) and 2(b), each of the heaters 10 includes a heating element 10a and a metallic heat transfer member 10b thermally connected to the heating element 10a.

The heat generated by the heating element 10a is conducted to the whole of the heat transfer member 10b, and the heat transfer member 10b is heated by the heating element as a whole. The uniformly heated heat transfer member 10b can uniformly heat the fluid heating section 1 from the outside. For that purpose, the heat transfer member 10b is preferably formed of a metal having good thermal conductivity, such as aluminum, silver, copper, gold, or the like.

In the present embodiment, a known cartridge heater is used as the eating element 10a. As the heat transfer member 10b, a member made of aluminum or an aluminum alloy disposed so as to surround the fluid heating section 1 is used. The heat transfer member 10b is configured by connecting parts made of aluminum by screwing or the like, and is provided so as to surround the fluid heating section 1 on the inside by, for example, fixing the bottom plate part, a pair of side wall parts, and the upper surface part in combination.

As the fluid control device 100 used in the semiconductor manufacturing device, it is preferable to select aluminum or an aluminum alloy as the material of the heat transfer member 10b because there is little concern of contamination to the process and it is relatively inexpensive. However, in other applications, other high thermal conductivity metal materials as described above may be used.

The heating element 10a of the heater 10 is inserted into and fixed to an elongated hole formed in a side wall portion of the heat transfer member 10b. The heating element 10a and the heat transfer member 1.0b are thermally connected and fixed so that heat from the heating element 10a is efficiently transferred to the heat transfer member l0b. In a preferred embodiment, the heating element 10a is fixed in close contact with an elongated hole provided in the heat transfer member 10b, and may be fixed to the heat transfer member 10b via a known thermally conductive material (such as a thermally conductive grease or a thermally conductive sheet) applied to the outside of the heating element 10a.

In the example shown in FIG. 2, in the first heater 12, the rod-shaped cartridge heater 10a is inserted into an elongated hole extending in the vertical direction downward from the upper end surface of the side wall portion of the heat transfer member lob, and in the second heater 14 and the third heater 16, the heating element 10a refracted in a L-shape is inserted into an elongated hole extending in the horizontal direction in which an opening is provided in the lateral end surface of the side wall portion of the heat transfer member 10b. However, various known heating devices can be used as the heating element, and for example, a planar heater fixed to the heat transfer member 10b may be used.

In addition, a horizontal direction portion 10y of the heating element 10a refracted in the L-shape is accommodated in the elongated hole of the heat transfer member 10b, but a vertical direction portion 10z is not inserted in the elongated hole, and thus may interfere with the connection between the heat transfer members 10b. In such a case, a concave portion 11z in which the vertical direction portion 10z can be accommodated is formed in advance in an end portion of the heat transfer member 10b, and when the horizontal direction portion 10y of the heating element 10a is inserted into the hole, the vertical direction portion 10z can be accommodated in the concave portion 11z so as not to hinder the connecting of the heat transfer member 10b.

In the example shown in FIG. 2, a temperature sensor 10c attached to the second heater 14 (a heater for heating the vaporizing section 4) is shown, and a temperature of the heat transfer member 10b of the second heater 14 can be directly measured.

The temperature of the first heater 12 is set to, for example, about 180° C., the temperature of the second heater 14 is set to, for example, about 200° C., and the temperature of the third heater 16 is set to, for example, about 21° C. Normally, the first heater 12 for heating the preheating section 2 is set to a temperature lower than that of the second heater 14 for heating the vaporizing section 4, and the third heater 16 for heating the fluid control section 6 is set to a temperature higher than that of the second heater 14. As described above, in the present embodiment, since the temperature of each heater can the individually controlled by using a control device (not shown), the vaporizer of the raw material, the preheating of the liquid raw material, and the prevention of the re-devolatilization of the vaporized raw material can be performed at appropriate temperature respectively.

The upper surface portion of the heat transfer member 10b may have any shape corresponding to the shape of an upper mounting member such as a valve or a pressure sensor mounted thereon. In this way, the heat transfer member 10b can perform heat transfer to the fluid heating section 1, and can also be appropriately used as a support member of the upper mounting member. As shown in FIG. 2(b), the bottom plate portion of the heat transfer member 10b may be attached to a common support 19 via a heat insulating member 18 made of a resin PEEK (Poly Ether Ether Ketone). The heat insulating member 18 may be formed of any material as long as heat can be shielded, and a material or the like may be appropriately selected in accordance with temperature.

In the present embodiment, a gap X is provided between the heat transfer member 10b of the first heater 12 and the heat transfer member 10b of the second heater 14, and between the heat transfer member 10b of the second heater 14 and the heat transfer member 10b of the third heater 16, respectively. As a result, even when the preheating section 2, the vaporizing section 4, and the fluid control section 6 are individually heated by using the heaters 12, 14, and 16, the thermal conductivity between the heaters is lowered, and therefore, the advantage of easily controlling the temperature to a desired temperature can be achieved.

Further, as shown in FIG. 1, a heat insulating member 13 made of PEEK is disposed in the gap between the heat transfer member of the first heater 12 and the heat transfer member of the second heater 14. Thereby, heat conduction from the second heater 14 and the vaporizing section 4 to the preheating section 2 is suppressed, so that it is possible to effectively prevent the preheating section 2 from becoming too hot to cause the raw material liquid being vaporized before being sent to the vaporizing section. In the present embodiment, the heat insulating member 13′ is also disposed downstream side of the fluid control section 6 (in the vicinity of a stop valve 56), so to suppress heat being transferred to the outside, and to easily maintain the fluid control section 6 at a high temperature. The heat insulating members 13 and 13′ may also be formed of any material or shape as long as heat can be shielded, and a material or the like may be appropriately selected in accordance with the temperature.

In the heater 10 configured as described above, as shown in FIG. 3, an inner surface of the aluminum heat transfer member 10b provided with the heating element 10a, that is, the surface facing the fluid heating section 1, includes a surface S1 subjected to alumite treatment or anodization as a surface treatment for improving heat dissipation. The outer surface of the heat transfer member includes a polished surface or a mirror finished surface S2. The mirror finished surface on the outer side of the heat transfer member 10b is typically formed by a polishing process, but may be formed only by machining.

The inner surface S1 of the heat transfer member 10b is anodized, in particular hard anodized, so that the heat dissipation can be improved. Heat h from the heating element 10a can be conducted directly from the heat transfer member 1.0b to the fluid heating section 1 when in contact, and can be conducted to the liquid heating section 1 with uniform and improved efficiency by high radiation even when the heat transfer member 10b and the fluid heating section 1 are at a distance.

Further, in the case where the fluid heating section 1 is in contact with the heat transfer member 10b, the heat h is conducted from the contact portion, but when the heat h is transferred from the heat transfer member 10b to the fluid heating section 1, if the inner surface of the heat transfer member 10b is not anodized, the heat h may be reflected on the inner surface of the heat transfer member 10b and may not be transferred to the fluid heating section 1 due to the emissivity. On the contrary, when the inner surface of the heat transfer member 10b is anodized as in the present embodiment, since the emissivity is high, almost no heat is reflected on the surface contacting the fluid heating section 1, and almost all of the heat h from the heat transfer member 10b is conducted to the fluid heating section 1.

For the above reasons, according to the heater 10 of the present embodiment, it is possible to improve the energy utilization efficiency and to achieve energy saving. In addition, it is possible to shorten the time for heating the liquid heating section 1 to a desired temperature.

Further, since the outer surface S2 of the heat transfer member 10b is mirror-finished, the reflectance is improved and the emissivity is lowered. Therefore, the heat radiation to the outside of the heater 10 can be suppressed, the heat radiation to the inside can be efficiently performed, so enemy saving can be achieved. In addition, since the amount of heat radiation to the outside is small and the surface temperature is maintained at a relatively low temperature, it is possible to relatively easily take measures against a high temperature at the outside. The outside of the fluid control device 100 is required to be maintained at a temperature of, for example, 60° C. or less for safety.

In a specific design example, the emissivity at 200° C. of the inner surface S1 (anodized surface) of the heat transfer member 10b is set to, for example, 0.950 (reflectivity 0.050), and the emissivity at 200° C. of the outer surface S2 (polished surface or mirror-finished surface is set to, for example, 0.039 (reflectivity 0.961). An arithmetic mean roughness of the minor-finished outer surface is set to Ra=0.1 a to 1.6 a, for example.

Hereinafter, a manufacturing procedure of the heat transfer member 10b of the heater 10 will be described with reference to FIGS. 4(a) to 4(c).

First, as shown in FIG. 4(a), an aluminum member (here, an aluminum plate) having a desired shape is prepared by cutting work. The aluminum member may be formed of aluminum or an aluminum alloy.

Next, as shown in FIG. 4(b), alumite treatment or anodization is applied on the entire surface of the aluminum member. In the present embodiment, so-called hard anodization is applied, and the thickness of the alumite layer formed on the surface (here, the total thickness of the porous alumina layer and the base layer) is relatively thick, for example, 20 μm m to 70 μm. The anodization may be performed by various known methods, but it is preferable that the treatment conditions are appropriately selected so as to obtain an effective alumite layer for improving heat dissipation.

Note that the anodization in the present embodiment is not limited to the hard anodization, and the same effect can be exhibited even in the normal anodization. The thickness of the alumite layer exhibits the same effect as long as it is formed by normal anodization (e.g., 1 μm or more). However, the hard anodization has an advantage that scratches are hardly generated during operation, and a concern about film peeling can be reduced as compared with the normal anodization.

Next, as shown in FIG. 4(c), only the outer surface S2 of the aluminum member whose entire surface has been anodized, that is, the outer surface S2 disposed opposite side of the side facing the fluid heating section 1, is reprocessed. In reprocessing, the alumite layer is removed and a minor finishing is applied, so that only the outer surface of the aluminum member becomes the mirror finished surface, while the other surfaces remain the anodized aluminum surface. The mirror finished surface may be formed by grinding the alumite layer and then performing a separate polishing treatment, or may be formed only by grinding the alumite layer using a known mirror surface grinding technique.

The heater can be manufactured by using the aluminum member obtained as described above, with the outer surface being mirror-finished, and the inner surface being anodized, and combining them so as to cover the outer side of the fluid heating section 1, and mounting the heating element 10a in the fine hole provided in the end surface of the side wall portion,

In the heater manufactured by the above procedure, only the outer surface of the heat transfer member 10b is a mirror-finished surface, and all surfaces other than the outer surface (including the inner surface and the end surface) are anodized surfaces. However, the end surface of the heat transfer member 10b may also be subjected to a process such as a polishing treatment to reduce the heat dissipation property. Alternatively, only the inner surface may be subjected to alumite treatment, and all other surfaces may be mirror-finished or processed solid surface (after normal processing, surface treatment or the like is not applied).

Hereinafter, a more specific configuration of the fluid control device 100 of the present embodiment will be described in detail with reference to FIG. 1 and the like.

The vaporizing section 4 includes a main body 40 formed by connecting a vaporizing block 41 made of stainless steel and a gas heating block 42. The vaporizing block 41 has a liquid supply port formed in an upper portion, and a vaporizing chamber 41a formed inside. In the gas heating block 42, a gas heating chamber 42a communicating with a gas flow path extending from the upper portion of the vaporizing chamber 41a is formed, and a gas discharge port is formed in the upper portion. The gas heating chamber 42a has a structure provided with a cylindrical heating accelerator inside a cylindrical space, and a gap between the cylindrical space and the heating accelerator serves as a gas flow path. The gas communication portion between the vaporizer block 41 and the gas heating block 42 is interposed with a gasket 43 having a through hole, and pulsation of the gas is prevented by the gas passing through the through hole of the gasket 43 having a through hole.

The preheating section 2 includes a preheating block 21 connected to the vaporizing block 41 of the vaporizing section 4 via a liquid filling valve 3. A liquid storage chamber 23 is formed inside the preheating block 21. The liquid storage chamber 23 communicates with a liquid inflow port 22 provided on the side surface and a liquid outflow port provided on the upper surface. The preheating block 21 stores a liquid raw material L, which is pressure-fed from a liquid storage tank (not shown) at a predetermined pressure, and preheats the liquid raw material L by using the first heater 12 before supplying the liquid raw material L to the vaporizing chamber 41a. Moreover, a columnar heating accelerator for increasing the surface area may also be disposed inside the liquid storage chamber 23.

A liquid filling valve 3 controls the supply amount of the liquid raw material L to the vaporizing section 4 by opening and closing or adjusting the opening degree of the supply passage 4 communicating with the preheating block 21 and the vaporizing block body using a valve mechanism. As the liquid filling valve 3, for example, an air-driven valve can be used. A gasket 44 formed with a narrow hole is interposed in the liquid supply port of the vaporizer block 41, and the supply amount into the vaporizing chamber 41a is adjusted by the liquid raw material passing through the narrow hole of the gasket 44.

In the present embodiment, the fluid control section 6 is a high-temperature compatible pressure type control device, and may have, for example, the configuration described in Patent Document 2. The high-temperature compatible pressure type control device includes, for example, a valve block as a main body provided with a gas flow path inside, a metal diaphragm valve element interposed in the gas flow path, a heat dissipation spacer and a piezoelectric driving element arranged in the longitudinal direction, an orifice member (such as an orifice plate) formed with a fine hole interposed in the gas flow path downstream side of the metal diaphragm valve element, and a flow rate control pressure detector for detecting a pressure in the gas flow path between the metal diaphragm valve element and the orifice member. The heat dissipation spacer is formed of an invar material or the like, and prevents the temperature of the piezoelectric driving element from becoming higher than the heat-resistant temperature even if a high-temperature gas flows through gas flow path. The high-temperature compatible pressure type control device is configured such that, when the piezoelectric driving element is not energized, the metal diaphragm valve element abuts against the valve seat to close the gas flow path, on the other hand, when the piezoelectric driving element is energized, the piezoelectric driving element expands, and the metal diaphragm valve element returns to the original inverted dish shape by the self-elastic force to open the gas flow path.

FIG. 5 is a diagram schematically showing a configuration example of the fluid control section 6 (pressure type flow rate control device). The pressure type flow rate control device 6 includes an orifice member 71, a control valve 80 composed of a metal diaphragm valve element and a piezoelectric driving element, and a pressure detector 72 and a temperature detector 73 provided between the orifice member 71 and the control valve 80. The orifice member 71 is provided as a restriction part, and a critical nozzle or a sonic nozzle may be used instead. An aperture diameter of the orifice or the nozzle is set to, for example, 10 μm to 500 μm.

The pressure detector 72 and the temperature detector 73 are connected to a control circuit 82 via an AD converter. The AD converter may be incorporated in the control circuit 82. The control circuit 82 is also connected to the control valve 80, generates a control signal based on the outputs of the pressure detector 72 and the temperature detector 73, and controls the operation of the control valve 80 according to the control signal.

The pressure type flow rate control device 6 can perform the flow rate control operation same as that of a conventional one, and can control the flow rate based on an upstream pressure P1 (pressure upstream side of the orifice member 71) by using the pressure detector 72. In another embodiment, the pressure type flow control device 6 may also include a pressure detector downstream side of the orifice member 71, and may be configured to detect the flow rate based on both the upstream pressure P1 and a downstream pressure P2.

In the pressure type flow rate control device 6, the flow rate control is performed by using the following principle: when the critical expansion condition P1/P2≥about 2 (P1: gas pressure (upstream pressure) upstream side of the restriction part, P2: gas pressure (downstream pressure) downstream side of the restriction part, and about 2 is for nitrogen gas and the flow rate of the gas passing through the restriction part is fixed to the sonic velocity, the flow rate is determined by the upstream pressure P1 regardless of the downstream pressure P2. When the critical expansion condition is satisfied, a flow rate Q downstream of the restriction part is given by Q=K₁·P1, where K₁ is a constant dependent on the fluid type and the fluid temperature, and the flow rate Q is proportional to the upstream pressure P1. When the downstream pressure sensor is provided, the flow rate can be calculated even when the difference between the upstream pressure P1 and the downstream pressure P2 is small and the critical expansion condition is not satisfied, and the flow rate can be calculated from a predetermined equation Q=K₂·P2^{m} (P1−P2)ⁿ (where K₂ is a constant depending on the type of the fluid and the fluid temperature, m and n are exponents derived from the actual flow rate) based on the upstream pressure P1 and the downstream pressure P2 measured by each pressure sensor.

The control circuit 82 obtains the flow rate from the above Q=K₁·P1 or Q=K₂ P2^{m} (P1−P2)ⁿ by calculation based on the output (upstream pressure P1) of the pressure detector 72 or the like, and feedback-controls the control valve 80 so that the flow rate approaches the set flow rate inputted by the user. The flow rate obtained by the calculation may be displayed as a flow rate output value.

In the fluid control device 100 of the present embodiment, as shown in FIG. 1, a spacer block 50 is connected to a gas heating block 42, and the valve block of the fluid control device 6 is connected to the spacer block 50. The gas flow path in the flow path block 5 fixed so as to straddle the gas heating block 42 and the spacer block 50 communicates the gas heating chamber 42a of the gas heating block 42 with the gas flow path of the spacer block 50. The gas flow path of the spacer block 50 communicates with the gas flow path of the valve block of the fluid control device 6. A stop valve 56 is provided in the gas flow path downstream side of the fluid control section 6, to shut off the gas flow as necessary. As the stop valve 56, for example, a known air operated valve or electromagnetic valve can be used. The downstream side of the stop valve 56 is connected to, for example, a process chamber of a semiconductor manufacturing device, and when gas is supplied, the inside of the process chamber is depressurized by a vacuum pump, and a material gas of a predetermined flow rate is supplied to the process chamber.

While the embodiments of the present invention have been described above, it is needless to say that various modifications are possible within a range that does not depart from the spirit of the present invention.

### INDUSTRIAL APPLICABILITY

Fluid-control devices according to embodiments of the present disclosure may be used, for example, in MOCVD semiconductor-manufacturing equipment to provide fluid gases having high temperature to a processing chamber.

### DESCRIPTION OF NUMERICALS

1 Fluid heating section

2 Preheating section

3 Liquid filling valve

4 Vaporizing section

5 Flow path block

6 Fluid heating section

7 Pressure detector

10 Heater

12 First heater

14 Second heater

16 Third heater

71 Orifice member

80 Control valve

100 Fluid rate control device

1. A fluid control device comprising:
a fluid heating section provided with a flow path or a fluid accommodating portion inside; and
a heater for heating the fluid heating section,
wherein the heater includes a heating element and a heat transfer member thermally connected to the heating element and arranged to surround the fluid heating section, and
a surface of the heat transfer member facing the fluid heating section includes a surface treated for improving heat dissipation.

2. The fluid control device according to claim 1, wherein the heat transfer member is formed of aluminum or an aluminum alloy, and the surface treated for improving the heat dissipation is an anodized surface.

3. The fluid control device according to claim 1, wherein the heat transfer member has an inner surface facing the fluid heating section, and an outer surface located opposite side of the inner surface, and the outer surface includes a polished surface.

4. The fluid control device according to claim 1, wherein the heat transfer member has an inner surface facing the fluid heating section, and an outer surface located opposite side of the inner surface, and the outer surface includes a mirror-finished surface.

5. The fluid control device according to claim 1, wherein the heat transfer member is formed from aluminum or an aluminum alloy and has an inner surface facing the fluid heating section and an outer surface located opposite side of the inner surface, and the outer surface of the heat transfer member is a mirror-finished surface or polished surface, and all surfaces of the heat transfer member other than the outer surface are anodized surfaces.

6. The fluid control device according to claim 1, comprising: a vaporizing section; a preheating section for preheating a liquid supplied to the vaporizing section; and a fluid control measuring section for controlling or measuring a gas delivered from the vaporizing section, wherein the fluid heating section is at least any one of the vaporizing section, the preheating section, and the fluid control measuring section.

7. The fluid control device of claim 6, wherein a gap is provided between a heat transfer member of a first heater for heating the preheating section and a heat transfer member of a second heater for heating the vaporizing section.

8. The fluid control device according to claim 7, further comprising a heat insulating member provided in the gap between the heat transfer member of the first heater and the heat transfer member of the second heater.
